(19) United States
(12) Patent Application Publication
(10) Pub. No.: US 2026/0047046 A1
(43) Pub. Date: Feb. 12, 2026

(54) Bleed-in Reservoir For Improved All-In-One (AIO) System Longevity and Performance

(71) Applicant: JetCool Technologies Inc., Littleton, MA (US)

(72) Inventors: Ludwig C. HABER, Littleton, MA (US); John Grischuk, Littleton, MA (US); Daniel Sweeney, Littleton, MA (US); Alaina Schiano, Littleton, MA (US); Joe Koelle, Littleton, MA (US)

(73) Assignee: JetCool Technologies Inc., Littleton, MA (US)

(21) Appl. No.: 19/292,325

(22) Filed: Aug. 6, 2025

Related U.S. Application Data
(60) Provisional application No. 63/679,987, filed on Aug. 6, 2024.

(51) Int. Cl. H05K 7/20

(52) U.S. Cl. CPC H05K 7/20272

(57) ABSTRACT

A liquid cooling system for an electronic device includes a bleed-in reservoir configured to facilitate the separation and removal of entrained gases from a circulating liquid coolant. The bleed-in reservoir is fluidly connected to the main cooling loop of the cooling system via a parallel branch comprising smaller-diameter fluid conduits to ensure a reduced flow rate of liquid coolant through the parallel branch compared to the flow rate through the main cooling loop. The bleed-in reservoir includes an internal chamber configured to receive and hold liquid coolant and a compressible gas volume, and may incorporate internal flow modifying features, such as flow diverters, baffles or perforated plates, to increase residence time, induce turbulence, and enhance gas-liquid separation. Strategic placement of the inlet and outlet ports along the vertical height of the internal chamber walls promotes gravitational separation by leveraging the buoyancy properties of the gas. In some embodiments, multiple bleed-in reservoirs may be connected in series along the parallel branch to increase gas handling capacity. The disclosed system improves thermal performance, extends operational lifespan, and reduces maintenance by progressively removing gas from the liquid cooling system without compromising pressure requirements in the main cooling loop.

### FIELD OF THE INVENTION

The present invention relates generally to liquid cooling systems for managing heat generated by electronic components in high-performance computing (HPC) environments, data centers, electric vehicles (EVs), and other electronic devices. More specifically, the invention pertains to reservoir structures used within such liquid cooling systems.

### BACKGROUND

Modern computer processing devices (e.g., CPUs, GPUs, FPGAs, ASICs, etc.) used in high-performance computing environments, data centers, and electric vehicles (EVs) generate substantial heat due to high transistor densities, increased clock speeds, multiple cores and threads, execution of power-hungry instructions and workloads, and static power losses. To manage this heat, many systems employ air-assisted liquid cooling solutions, often referred to as “All-In-One” (AIO) liquid cooling systems because they are self-contained and typically serve individual compute nodes or servers, dissipating heat to the surrounding facility air.

In a typical AIO configuration, a liquid coolant circulates through a closed loop, comprising a pressure source (such as a pump), a cooling module, an inline radiator, an inline reservoir and a series of fluid conduits, such as hoses, tubes, pipes, connectors and valves, fluidly connecting all of these components together. The cooling module is thermally coupled to one or more heat-generating components, such as a CPU or GPU. As the coolant flows through the cooling module, it absorbs heat from the heat-generating components, thereby cooling the heat-generating components. The heated coolant is then directed to the inline radiator via the conduits, and the radiator rejects the absorbed heat to the surrounding air, which cools the liquid. The cooled liquid is then circulated through the reservoir and back to the cooling module to repeat the cooling process. This closed-loop cycle operates continuously while the compute node remains active. The order of components in this loop does not affect its main function. Arrangements of the components are based on space availability for the most part with limited impact on performance or reliability.

Despite their compact design and thermal efficiency, AIO liquid cooling systems have seen limited adoption in data center environments due to concerns about reliability, maintenance and limited operational lifespans. Although AIO liquid cooling systems are sealed and typically do not exhibit overt leakage, long-term phenomena, such as coolant permeation through construction materials and vapor transpiration at seals or interfaces, gradually reduce coolant volume. These phenomena reduce cooling system performance, limit operational lifespans of the cooling system, and increase the amount of time and resources that must be devoted to periodic maintenance. While such drawbacks may be acceptable for consumer or hobbyist markets, they are unsuitable for the operational demands of enterprise-level data centers. Although certain reliability issues can be mitigated through engineering solutions, the reduced performance, limited service life and increased maintenance costs associated with using AIO systems remains a significant barrier to widespread adoption in data centers.

A further challenge arises from thermal expansion of the coolant during operation. Completely filling an AIO system with liquid coolant fluid leaves no room for thermal expansion, which can lead to excessive internal pressure. To mitigate this problem, a small volume of compressible air is typically included within the cooling loop to act as a thermal expansion buffer. While this headspace helps to limit pressure spikes, it introduces the potential for liquid coolant/air interfaces in the closed loop. These liquid coolant/air interfaces are prone to turbulence, particularly within the inline reservoir component of the cooling loop, which may lead to air entrainment, where air is drawn into the coolant in the form of microbubbles. Such air entrainment can impair thermal performance and circulation efficiency.

Even when initial designs minimize turbulent interactions at the coolant/air interface, long-term coolant loss or air ingress can lead to the formation of unstable interfaces and increased entrainment over time. The inline reservoir, being a place where fluid accelerates and decelerates within the cooling loop, is particularly susceptible to this problem.

To address these issues, the present invention introduces a bleed-in reservoir design that increases the available headspace to mitigate fluid losses and thermal expansion, while isolating the air volume in a manner that minimizes turbulence and reduces the risk of air entrainment.

### SUMMARY OF THE INVENTION

The present invention provides a reservoir configuration for a liquid cooling system, such as an All-In-One (AIO) system, used to cool heat-generating electronic components. The reservoir, hereinafter referred to as a “bleed-in reservoir,” is fluidly connected to the main coolant loop via a parallel flow path (or parallel branch). This parallel flow path may be formed in relation to any primary component of the AIO cooling system, such as the pump, the radiator, the cooling module, or any tubing section in the main loop. In some embodiments, the bleed-in reservoir is disposed in parallel with the pump, forming a recirculation circuit. In other embodiments, the bleed-in reservoir is disposed in parallel with the inline radiator, or in parallel with the cooling module, or in parallel with a section of tubing that fluidly connects all of the other components of the main loop. In still other embodiments, the bleed-in reservoir forms a bypass path separate from the main loop flow.

The parallel branch is configured so that the flow rate through the bleed-in reservoir branch is substantially less than the flow rate through the main cooling loop. This configuration reduces the flow momentum in the parallel branch, which permits the bleed-in reservoir to function as a gas separation and accumulation zone, where gas present in the coolant, whether entrained or introduced through long-term permeation, can collect without substantially interfering with main loop operation. The bleed-in reservoir may include headspace to accommodate expansion of the liquid coolant or ingress of gases over the service life of the system. The bleed-in reservoir may also include diverter structures and/or baffles designed to increase the time that the coolant fluid remains in the bleed-in reservoir, thereby permitting more gas separation and accumulation in the headspace of the bleed-in reservoir.

The use of small-diameter fluid conduits between the parallel branch and the main loop also facilitates flexible positioning of the bleed-in reservoir in confined spaces, such as within a server enclosure. Moreover, because the bleed-in reservoir is not connected in series with the main cooling loop, it does not add substantially to the main loop's hydraulic resistance.

Generally, embodiments of the present invention provide a liquid cooling system for a heat-generating electronic device comprising a main cooling loop, a parallel branch and two fluid junction fittings connecting the parallel branch to the main cooling loop. The main cooling loop comprises a pump, a radiator, a cooling module configured to be put in thermal communication with the heat-generating electronic device, and a set of primary fluid conduits that fluidly connect the pump, the radiator and the cooling module in series to define a closed-loop flow path for circulating a liquid coolant. The liquid coolant circulates through the main cooling loop at a first flow rate determined by operation of the pump.

The parallel branch comprises a set of secondary fluid conduits connected in series with a bleed-in reservoir having an internal chamber comprising an inlet for admitting liquid coolant into the internal chamber, an outlet for discharging liquid coolant from the internal chamber, and headspace for capturing and holding a volume of compressible gas.

The internal chamber of the bleed-in reservoir is further configured to induce or enhance the separation of gas from liquid in the portion of the liquid coolant flowing through it, and to capture and confine the separated gas in the headspace, which prevents the separated gas from reentering the main cooling loop.

The two fluid junction fittings connect the secondary fluid conduits of the parallel branch to the main cooling loop so that the parallel branch is connected in parallel with a section of the main cooling loop. Connecting the parallel branch to a section of the main cooling loop in this manner permits a small portion of the liquid coolant circulating in the main cooling loop to be redirected into the parallel branch so that it flows through the bleed-in reservoir. While the portion of liquid coolant is passing through the bleed-in reservoir, at least some of the gas in the portion of liquid coolant is separated and removed from the liquid coolant before the liquid coolant is returned to the main cooling loop. Meanwhile, the larger portion of the liquid coolant (that portion that did not flow into the parallel branch) continues to circulate through the main cooling loop.

The internal chamber of the bleed-in reservoir may also include one or more flow-diverting structures (e.g., inserts, perforated plates and/or baffles) configured to promote or enhance the gas separation and confinement processes taking place inside the internal chamber.

Importantly, the set of secondary fluid conduits in the parallel branch are constructed to have smaller diameters than the primary fluid conduits in the main cooling loop. The smaller diameters of the secondary fluid conduits create considerably more resistance to the flow of liquid coolant through the parallel branch compared to the resistance existing in the main cooling loop. This ensures a reduced flow rate for the portion of the liquid coolant flowing through the parallel branch compared to the flow rate for the liquid coolant circulating through the main cooling loop. This arrangement also ensures that there is no significant increase in fluid pressure drop in the main cooling loop. The diversion of some of the liquid coolant into the parallel branch ensures that the total loop pressure drop will remain nearly unchanged.

The connection of the parallel branch to a section of the main cooling loop puts the bleed-in reservoir in a parallel flow relationship to the section of the main cooling loop that lies between the two junctions. This section of the main cooling loop may include the pump, or the radiator, or the cooling module, or a combination of these. The section put into parallel with the bleed-in reservoir might also include a segment of the set of primary fluid conduits in the main cooling loop, without including the pump, the radiator or the cooling module.

In addition to the structural features listed above, other embodiments of the present invention provide a corresponding method for operating a liquid cooling system for a heat-generating electronic device, wherein the liquid cooling system comprises a parallel branch with a bleed-in reservoir. The method may include the steps of (1) circulating a liquid coolant through a main cooling loop at a first flow rate, the main cooling loop comprising a pressure source (such as a pump), a radiator and a cooling module in thermal communication with the heat-generating electronic device; (2) diverting a portion of the liquid coolant to flow out of the main cooling loop and through a bleed-in reservoir that is connected in parallel to a section of the main cooling loop, the bleed-in reservoir comprising an internal chamber with headspace for capturing a volume of compressible gas; (3) maintaining a flow in the bleed-in reservoir that is substantially lower than the flow rate in the main cooling loop; and (4) permitting gas in the portion of liquid coolant flowing through the bleed-in reservoir to be separated from the liquid coolant and confined in the headspace of the internal chamber, thereby preventing the gas confined in the headspace of the internal chamber from reentering the main cooling loop.

The method may optionally further include selecting the reservoir conduit dimensions such that the reservoir may be positioned in nonstandard or space-limited regions of an electronic enclosure, and/or maintaining system pressure within operating thresholds by accommodating thermal expansion in the reservoir headspace.

In accordance with additional embodiments of the present invention, the bleed-in reservoir may be integrated directly into one or more components of the main cooling loop, thereby eliminating the need for separate fluid junction fittings or external parallel branch conduits. In such embodiments, the reservoir is formed within or attached to the structure of a primary cooling system component—such as a pump housing, a cooling module body, or a radiator—so as to define an internal reservoir volume that is in fluid communication with the main coolant flow path. Alternatively, the reservoir may be incorporated into an endcap or fluid connector that is mechanically and fluidly coupled to the downstream end of such a component.

When the bleed-in reservoir is integrated into a cooling loop component or its associated endcap, a parallel flow path is formed internally, such that a portion of the liquid coolant flowing through the component is diverted into the reservoir while the remainder continues along the main flow path. This creates a bifurcated flow condition, with the diverted portion of the coolant passing through the built-in bleed-in reservoir in a pressure- and flow-parallel relationship with the un-diverted portion of the coolant that remains in the main flow circuit.

These integrated configurations improve system compactness and reliability by reducing the number of fluid connections required, while still enabling the bleed-in reservoir to perform its core function of removing entrained gas from the coolant stream and accommodating thermal expansion within the cooling system.

By implementing these bleed-in reservoir structures and corresponding methods, embodiments of the invention provide a cooling approach adapted to the long-term thermal and spatial constraints of compact electronic systems, such as those found in data centers, electric vehicles, or other high-performance computing environments.

### BRIEF DESCRIPTION OF THE FIGURES

The accompanying drawings, which are incorporated in and constitute part of the specification, illustrate preferred embodiments of the invention, and, together with the description, serve to explain the principles of the present invention. In the drawings, like reference numbers indicate identical or functionally similar elements. Additionally, unless otherwise indicated, the left-most digit(s) of a reference number identifies the drawing in which the reference number first appears.

FIG. 1 is a schematic diagram of a conventional AIO cooling system in which a reservoir is connected in series with other components of the cooling loop.

FIG. 2 is a schematic diagram of an AIO cooling system constructed in accordance with an exemplary embodiment of the present invention, in which a bleed-in reservoir is connected in parallel with the radiator component of the main cooling loop.

FIG. 3 shows another schematic diagram of an AIO cooling system in which the bleed-in reservoir is connected to a parallel branch, and the parallel branch is configured to divert a small portion of the total coolant flow.

FIG. 4 is an electrical circuit diagram used to analogize the pressure distribution across the AIO cooling system shown in FIG. 3.

FIG. 5 is an electrical circuit diagram used to analogize an embodiment in which the bleed-in reservoir is connected in parallel with the pump.

FIG. 6 is an electrical circuit diagram used to analogize an embodiment in which multiple bleed-in reservoirs are connected in series within a parallel branch of the cooling system.

FIG. 7 is a schematic diagram showing gas-liquid separation within a bleed-in reservoir, including the formation of bubbles due to density differences between liquid coolant and entrained air.

FIG. 8 is a schematic diagram showing an alternative reservoir inlet configuration designed to reduce turbulence and promote stable gas separation.

FIG. 9A is a schematic diagram showing an early stage of bubble separation in a bleed-in reservoir when an aerated coolant first enters the bleed-in reservoir.

FIG. 9B is a schematic diagram showing a later stage in which gas has accumulated in the upper portion of the bleed-in reservoir and degassed liquid coolant exits through the outlet.

FIG. 10A is a top-down schematic view of a bleed-in reservoir without a flow-diverting structure, illustrating direct flow from inlet to outlet.

FIG. 10B is a top-down schematic view of a bleed-in reservoir with a flow diverter, showing redirected flow that increases residence time and turbulence.

FIG. 11 is a side view schematic diagram of a bleed-in reservoir divided into upper and lower chambers by a perforated plate to promote gravity-assisted separation of entrained gas.

FIG. 12 shows a rotation-inducing flow-diverting insert that introduces a swirling motion inside the bleed-in reservoir to increase residence time and promote bubble disengagement.

FIG. 13 shows a redirection-type flow-diverting insert configured to deflect incoming fluid flow away from the outlet.

FIG. 14 shows a blocking flow-diverting insert that prevents surface-level aerated coolant from reaching the outlet by directing flow along the bleed-in reservoir's floor.

FIG. 15 shows of a labyrinth-style flow-diverting insert that maximizes residence time near the liquid surface to enhance degassing.

FIG. 16 is a schematic view of a baffled reservoir design that reduces outlet submergence requirements, increasing usable fluid volume before air entrainment occurs.

FIG. 17 shows an installation of a bleed-in reservoir within a server enclosure, including routing of small-diameter tubing through existing backplane openings.

FIG. 18 shows a bleed-in reservoir with a baffled insert that hydraulically isolates a longer residence-time chamber from the outlet flow path.

FIG. 19 shows the internal geometry of a bleed-in reservoir having flow diverters integrated into the bleed-in reservoir's floor to enhance gas separation, wherein the flow diverters also function as structural stiffeners.

FIG. 20 is a schematic top-down view of a radiator endcap incorporating an integrated bleed-in reservoir, in which a portion of the incoming coolant flow is diverted into the reservoir while the remainder continues along the main flow path.

FIG. 21 is a schematic top-down view of an alternative radiator endcap incorporating an integrated bleed-in reservoir with internal routing configured to promote gravitational gas separation and discharge of de-aerated coolant back into the main flow path.

### DETAILED DESCRIPTION OF EXEMPLARY EMBODIMENTS

Reference will now be made in detail to exemplary embodiments of the present invention, examples of which are illustrated in the accompanying drawings. Notably, embodiments of the present invention may be implemented in a variety of different ways and for a variety of different industrial applications, as would be apparent to those of skill in the art after reading this disclosure. The figures and examples described below are not meant to limit the scope of the present invention or its embodiments or equivalents.

The present invention provides improvements in liquid cooling systems, particularly All-In-One (AIO) cooling circuits used in various electronic systems, including, but not limited to, those deployed in data center infrastructure. The invention is directed to enhancing the longevity, reliability, and thermal performance of AIO systems through a modified reservoir configuration and associated flow path arrangements.

In one aspect, there is provided an AIO cooling system comprising a bleed-in reservoir (sometimes referred to in the industry as a “bleed-in tank”) fluidly connected to the main coolant loop via a parallel branch. The parallel branch containing the bleed-in reservoir is connected in parallel with one or more differential pressure-generating components in the main cooling loop, such as the radiator, pump, or cooling module. The parallel connection enables multiple technical effects. First, it reduces the pressure differential across the pump by removing the reservoir from the serial flow path, thereby allowing increased coolant flow or reduced pump power consumption. Second, it provides more flexibility in terms of reservoir placement in a server or in an enclosure due to the reduced size of the connecting conduits in the parallel branch. The small-diameter tubing in the parallel branch can be routed through confined internal pathways typical of server racks and enclosures. Third, it improves the gas separation process in the reservoir because of the reduced flow velocity through the parallel branch and the reservoir, which increases residence time and promotes bubble disengagement and accumulation of gases in the headspace of the reservoir. Fourth, it maximizes reservoir efficiency by lowering the critical volume threshold (i.e., the volume at which outlet flow begins to entrain gas), thus increasing working volume in the system before performance degradation starts to occur.

An AIO cooling system constructed and operated according to one embodiment of the present invention comprises a pump configured to drive coolant through a main cooling loop, one or more cooling modules in the main cooling loop, the cooling modules being thermally coupled to one or more heat sources (e.g., CPUs, GPUs), respectively, a radiator on the main cooling loop configured to transfer heat from the coolant to ambient air, and a bleed-in reservoir fluidly connected to the main cooling loop via a low-flow-rate parallel branch. The bleed-in reservoir is configured to enhance and manage gas separation and volume compensation in the AIO cooling system.

The closed loop and low-flow parallel branch may include conduits connecting the system components. But in some embodiments, the system components may be directly integrated or co-located such that no discrete tubing is required between them. In all configurations, air must be supplied to the radiator to facilitate heat rejection, either from server-installed fans or from optional fans integrated into the AIO system itself.

The bleed-in reservoir may be connected in parallel with any other system component, such as the radiator, the cooling module, or the pump, depending on the desired pressure differential and flow path design. In a typical embodiment, the bleed-in reservoir is connected in parallel with the radiator, where pressure drop across the radiator provides the motive force to circulate coolant through the bleed-in reservoir. Flow regulation elements (e.g., valves, orifices, capillaries, or passive flow restrictors) may be used to control flow through the parallel branch and bleed-in reservoir, with target flow rates typically limited to less than a few percent of the flow in the main cooling loop. The low flow rate through the bleed-in reservoir promotes more effective separation and accumulation of gases introduced into the system by the permeation of coolant fluid through the seals and connections, or by vapor ingress over the system's operational lifetime.

In some embodiments, one or more of the following optional features may be implemented: (a) multiple bleed-in reservoirs may be connected in series or in parallel within the parallel branch to enhance gas disengagement and increase available fluid volume; (b) internal structures, such as flow inserts to increase fluid residence time, surface-enhancing structures, may be positioned inside the internal chamber of the bleed-in reservoir to optimize gas separation to improve gas disengagement, and shear-inducing baffles or geometries to assist in bubble migration to the free surface; and (c) the internal chamber of the bleed-in reservoir may include outlet features, such as baffled outlets and baffled cavities, to reduce the critical reservoir level and delay gas entrainment during discharge.

To improve the migration of entrained gas toward the bleed-in reservoir, the first fluid junction fitting may be used to connect the upstream end of the parallel branch directly to a quiescent zone within the main cooling loop, such as a plenum region of a radiator or a low-velocity chamber within a cooling module. These regions are more likely to accumulate gas over time, and preferentially routing flow from such regions into the parallel branch and bleed-in reservoir encourages gas migration and separation before performance is impacted. Additionally, the second fluid junction fitting located at the downstream end of the parallel branch may be suitably connected to a quiescent zone of the main cooling loop to assist in flushing such quiescent zones, thereby preventing gas buildup in those locations. By incorporating these features and optional configurations, embodiments of the present invention provide a scalable, modular solution that enhances the operational reliability and efficiency of AIO cooling systems in constrained and thermally demanding electronic environments.

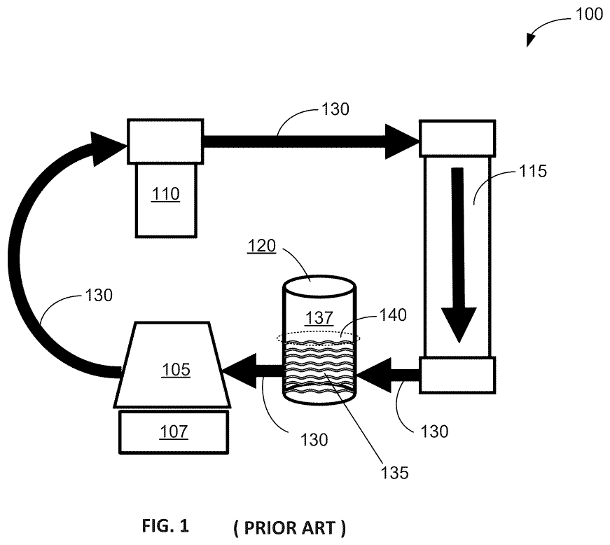

Turning now to the figures, FIG. 1 shows a conventional AIO cooling system 100, comprising a cooling module 105, a pump 110, a radiator 115, a reservoir 120, and a series of conduits 130 that fluidly tie all of these components together to define a main cooling loop. Although the conduits are shown as arrows in FIG. 1, it should be understood that the conduits 130 may comprise any appropriate number of connectors, hoses, tubes, passageways, pipes, channels, valves, or some combination thereof, to permit the liquid coolant to flow through all the components of the man cooling loop in the direction indicated by the arrows.

The cooling module 105 is in thermal communication with a heat-generating device 107, such as a CPU or GPU, although the heat-generating electronic device 107 is not itself fluidly coupled to the main cooling loop. As shown in FIG. 1, the reservoir 120 is connected in series (i.e., inline) with the other components in the flow circuit. Therefore, all of the liquid coolant 135 that flows through the flow circuit 130 of the cooling system 100 passes through the inline reservoir 120 on every cycle.

By design, the inline reservoir 120 contains both liquid coolant 135 and a volume of compressible air 137, which serves to accommodate the expected thermal expansion of the coolant during operation of the cooling system 100. But due to the presence of this compressible air volume 137, the pressure inside the inline reservoir 120 is lower than the pressure experienced by other components in the flow circuit. As a result of this reduced pressure, liquid coolant flows through the inline reservoir 120 at a slower rate than through other sections of the flow circuit. This comparatively lower flow velocity renders the reservoir 120 more susceptible to the accumulation of gas over time.

This gas accumulation that occurs in the reservoir 120 is primarily attributed to long-term mechanisms such as coolant permeation through system materials and vapor transpiration at seals or interfaces. These phenomena also contribute to a gradual reduction in coolant volume within the flow circuit. Over time, these conditions are likely to cause the formation of a liquid coolant/air interface 140 within the reservoir 120. This liquid coolant/air interface 140 is prone to turbulence, which can result in air entrainment, where air is drawn into the coolant in the form of microbubbles. The extent of air entrainment in the reservoir 120 is expected to increase progressively. If left unmitigated, the gas accumulation and air entrainment can impair both the thermal performance of the cooling module 105 and circulation efficiency of the AIO cooling system 100 as a whole, ultimately increasing the operational costs and maintenance requirements of the AIO cooling system 100, while simultaneously reducing its operational lifespan.

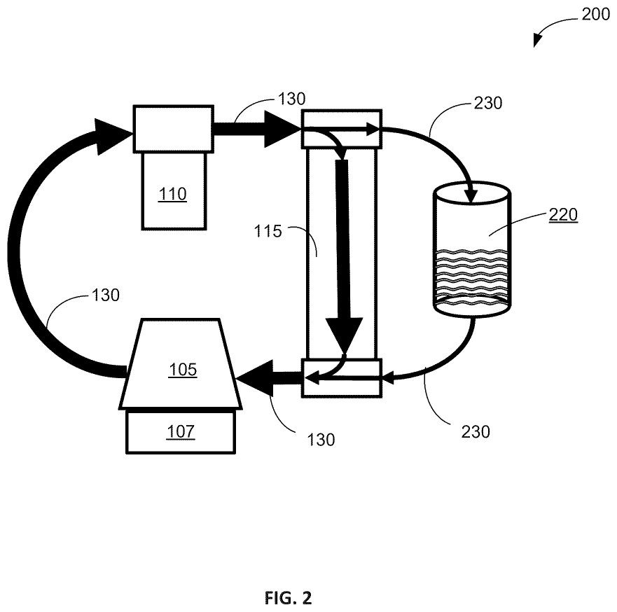

FIG. 2 shows an AIO cooling system 200 constructed and operated according to an exemplary embodiment of the present invention. As shown in FIG. 2, a parallel branch is added to the original flow circuit. The parallel branch includes two secondary fluid conduits 230 and a bleed-in reservoir 220, connected in parallel to another element within the main cooling loop (in this case the radiator 115). It should be noted, however, that, in other embodiments, the parallel branch containing the secondary fluid conduits 230 and the bleed-in reservoir 220 may be connected in parallel to other elements in the main cooling loop, such as the pump 110, the cooling module 105 or one or more of the conduits 130 in the main cooling loop, without departing from the scope of the claimed invention.

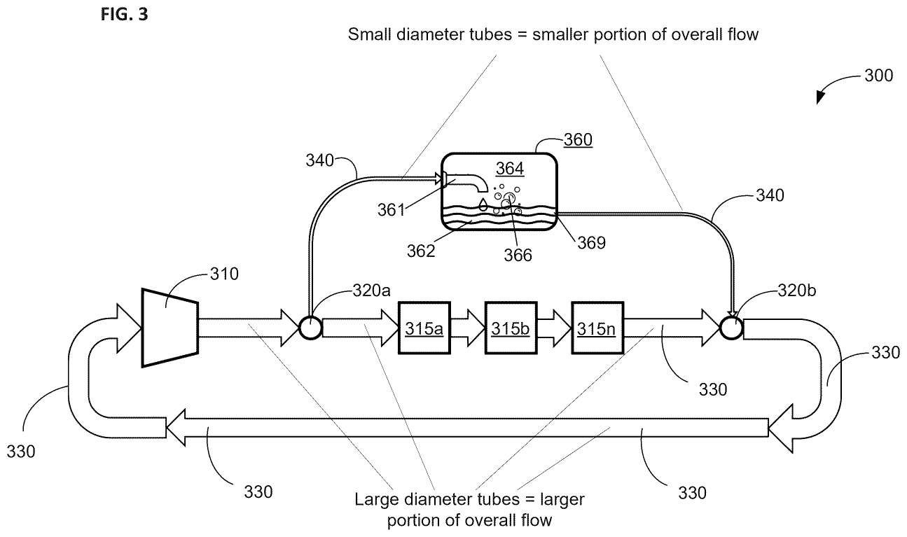

FIG. 3 illustrates a schematic diagram of an AIO cooling system 300 constructed in accordance with one embodiment of the present invention. As depicted, the main cooling loop comprises a plurality of primary fluid conduits 330, a pump 310 and a plurality of working elements 315a, 315b through 315, such as radiators, cooling modules, or other components, connected in series. For the cooling system 300 to operate efficiently, the main cooling loop must maintain a relatively high fluid pressure to ensure effective circulation through the working elements 315a through 315n.

In systems that require high fluid pressure for proper component operation, like the system illustrated in FIG. 3, it is undesirable to place a fluid reservoir directly in the main cooling loop. This is because the construction of the reservoir may introduce an undesirable pressure drop that could impair overall system performance. To address this concern, the embodiment shown in FIG. 3 includes a parallel branch, which is fluidly coupled to the main cooling loop 330 via two fluid junction fittings 320a and 320b and two secondary fluid conduits 340. A bleed-in reservoir 360 is fluidly connected to the parallel branch rather than being inserted directly into the main cooling loop. This arrangement places the bleed-in reservoir 360 in parallel communication with the series-connected working elements 315a, 315b through 315n. The flow path defined by the parallel branch therefore allows a portion of the total liquid coolant flow to bypass the high-pressure path of the main cooling loop.

The fluid junction fittings 320a and 320b are configured to split a fluid-carrying tube or hose into multiple branches, and/or merge multiple tubes or hoses into a single flow path. Examples of fluid junction fittings that may be used for this purpose include, for example, splitters, T-fittings (or tee connectors), Y-fittings (or wye connectors), push-to-connect fittings, quick-disconnect fittings, dual inlet adaptors, Y reducers, or any other type of fitting designed to accept a single fluid input stream and split it into two fluid output streams, or designed to accept two fluid input streams and merge them into a single fluid output stream.

The bleed-in reservoir 360 includes an internal chamber comprising an inlet 361, and outlet 369 and sufficient headspace 364 to hold a volume of compressible air.

During operation of the system, entrained and permeated gas may separate from the liquid component 362 of the liquid coolant in the form of microbubbles 366, which will rise into and be captured by the headspace 364 of the internal chamber over time.

As further indicated in FIG. 3, the secondary fluid conduits 340 (e.g., hoses, tubes or pipes) used in the parallel branch are intentionally selected to have smaller diameters than the primary fluid conduits 330 used in the main cooling loop. These reduced-diameter secondary conduits 340 reduce the flow rate through the parallel branch relative to the flow rate in the main cooling loop. Conversely, the larger-diameter conduits 330 in the main cooling loop facilitate higher flow rates through the main cooling loop compared to the flow rates in the parallel branch. This design enables the bleed-in reservoir 360, located in the low-flow parallel branch, to perform its principal function, namely, providing additional coolant capacity and headspace to accommodate thermal expansion and confine gases, while minimizing its impact on the pressure profile across the working elements 315a through 315n.

The relative resistance of the parallel branch in the embodiment of the invention shown in FIG. 3 is in part determined by the diameters of the primary and secondary fluid conduits 330 and 340 in the two flow paths, respectively. Because the parallel branch is constructed to have narrower diameter conduits 340, it has a comparatively higher resistance than the main branch. Consequently, a smaller portion of the overall liquid coolant flow will travel along the parallel branch. This arrangement is very useful when the goal is to direct most of the flow down the main cooling loop defined by the primary fluid conduits 330—toward a working element, such as a heat exchanger—and only a small amount of flow to travel along the parallel branch, which in this case, is toward the bleed-in reservoir 360.

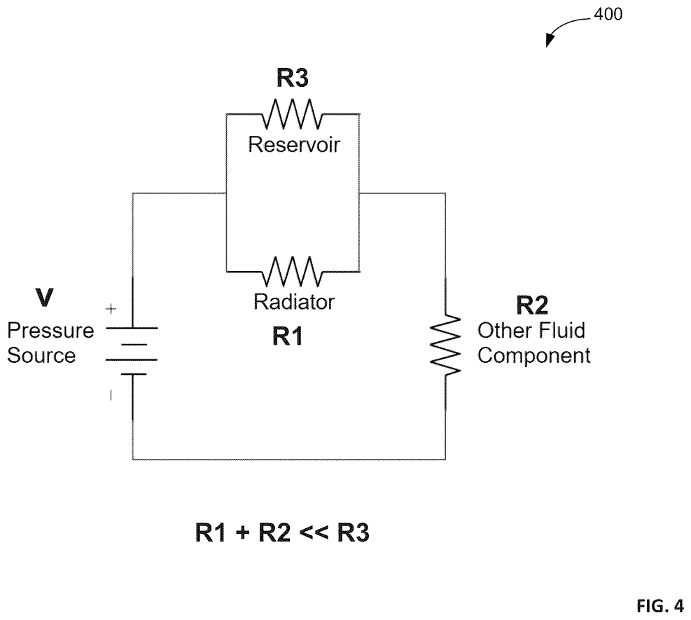

FIG. 4 presents a diagram of an electrical circuit 400 that serves as a useful analogy to illustrate a preferred pressure distribution across the cooling system 300 of FIG. 3 during operation, as would be desirable for optimal performance. In this analogy, the pump of the cooling system 300 functions analogously to the battery (V) in the electrical circuit by generating a pressure differential across the cooling loop, much like the battery (V) applies a voltage potential across the electrical circuit.

Similarly, the primary fluid conduits 330 in the cooling system 300 are selected based at least in part on their diameters, in order to control flow distribution in the same way that resistors in an electrical circuit are selected, based on their resistance values, to control current distribution. In this context, the radiator and other fluid components 315a to 315n in the main flow loop, along with the bleed-in reservoir 360, correspond to resistors R1, R2, and R3, respectively, in the electrical circuit 400.

The relative pressures in the branches of the main cooling loop and the parallel branch of FIG. 3 are analogous to the relative current levels in the branches of the electrical circuit 400 of FIG. 4. Specifically, FIG. 4 demonstrates that the flow behavior of the liquid coolant through the conduits of the cooling system is expected to mirror the behavior of electrical current through the illustrated circuit. More precisely, when the resistance values of resistors R1 and R2 are selected such that their combined resistance is significantly lower than the resistance of resistor R3, the majority of the electrical current will flow through the main circuit, including the battery (V), resistor R1 and resistor R2, while only a smaller portion of the current will flow through the parallel branch containing resistor R3.

By analogy, in the cooling system 300, appropriate sizing of the secondary fluid conduits 330 and 340 ensures that most of the coolant flows through the main loop (e.g., through the radiator and other working components 315a to 315n), while only a small fraction of the total flow is diverted through the parallel branch that includes the bleed-in reservoir 360. This controlled flow distribution minimizes the impact of the bleed-in reservoir 360 on system pressure and ensures effective thermal performance.

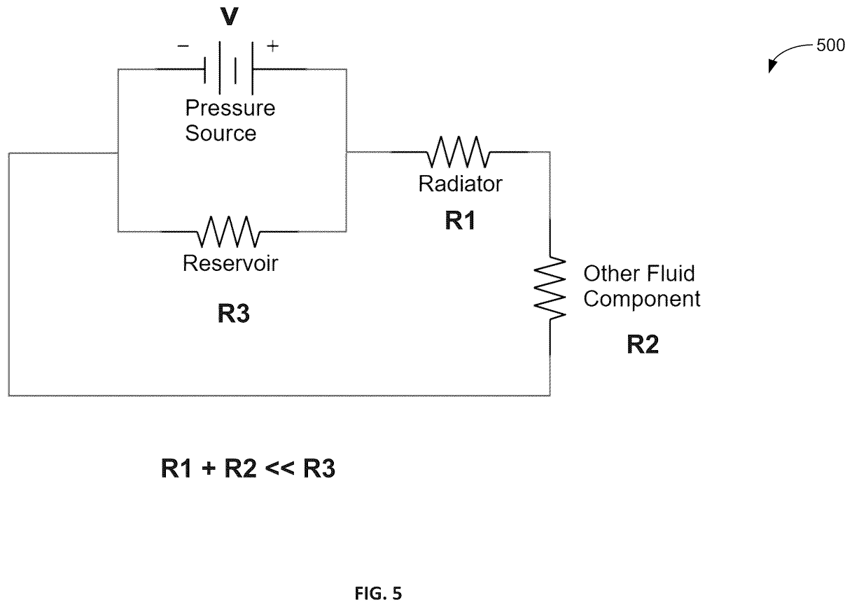

FIG. 5 illustrates a diagram of an electrical circuit 500 that, by analogy, represents a preferred pressure distribution across a cooling system constructed in accordance with another embodiment of the present invention. As with the embodiment shown in FIG. 4, this analogy is used to illustrate the hydraulic behavior of the cooling system using an equivalent electrical model. In the embodiment represented by the analogous electrical circuit shown in FIG. 5, the bleed-in reservoir is fluidly connected in parallel with the pump, such that a small portion of the liquid coolant exiting the pump outlet flows directly into and through the bleed-in reservoir and then returns directly to the pump inlet. In this configuration, the bleed-in reservoir is subjected to the maximum pressure differential within the loop, as it spans the pump's discharge and suction sides, based on the smaller diameters of the conduits in the bleed-in reservoir branch. Accordingly, the reservoir is effectively placed in parallel with the entire main cooling loop, including all working components such as the radiator and cooling modules.

As in the previous embodiment represented by FIGS. 3 and 4, flow through the bleed-in reservoir branch for the embodiment analogous to FIG. 5 is sustained by ensuring that the fluid conduits in the parallel branch are properly sized. When the conduit diameters are appropriately selected, the vast majority of the coolant will circulate through the main cooling loop (i.e., through the radiator and other components requiring high flow), while only a small fraction of the total flow is diverted through the reservoir branch. By analogy, as long as the resistance value of resistor R3 is substantially greater than the sum of the resistance values of resistors R1 and R2, only a fraction of the current flowing through the electrical circuit will flow over the path that includes the resistor R3 (which is the path analogous to the parallel branch containing the bleed-in reservoir). This arrangement enables the reservoir to perform its intended functions, such as accommodating gas accumulation and thermal expansion, without significantly affecting the pressure or flow dynamics of the main cooling circuit.

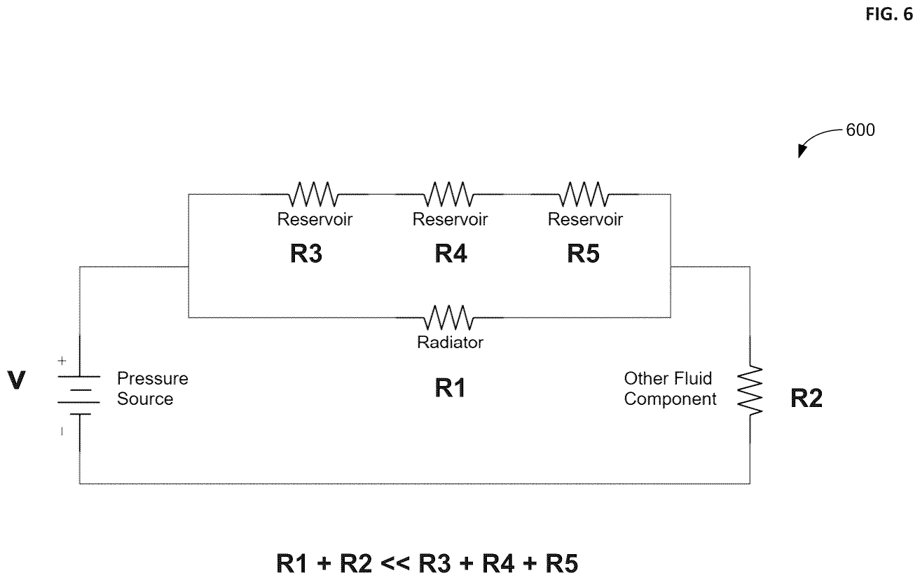

FIG. 6 illustrates another diagram of an electrical circuit 600 that, by analogy, models a preferred pressure distribution across a cooling system configured in accordance with a further embodiment of the present invention. In this embodiment, the bleed-in reservoir branch of the cooling system is connected in parallel with the radiator located in the main cooling loop. Unlike previous embodiments, the bleed-in reservoir branch in this case includes three bleed-in reservoirs connected in series.

In the electrical analogy shown in FIG. 6, the fluid conduits associated with the radiator and other fluid components in the main cooling loop correspond to resistors R1 and R2, while the bleed-in reservoir branch corresponds to resistors R3, R4, and R5, connected in series. To achieve the desired flow distribution and pressure profile, the combined resistance of R1 and R2 (representing the main circuit) should be substantially lower than the total resistance of R3, R4, and R5 (representing the reservoir branch). This ensures that the majority of the coolant (or current) flows through the main loop, while only a small, controlled amount of coolant (or current) is diverted through the bleed-in reservoir branch (or the R3, R4 and R5 branch of the electrical circuit).

Configuring multiple bleed-in reservoirs in series within the parallel branch provides increased gas separation, capture and storage capacity while preserving flexibility in the location, shape, and configuration of each bleed-in reservoir. This arrangement also maintains the benefits of the bleed-in reservoir approach, namely, accommodating thermal expansion and gas accumulation, without imposing a significant pressure drop on the main cooling loop.

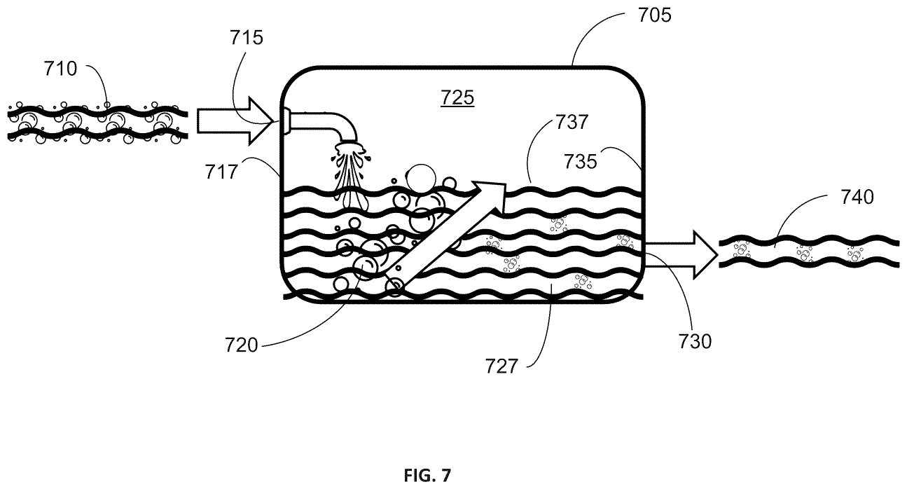

FIG. 7 shows a diagram that illustrates the separation of air from liquid flow within a bleed-in reservoir 705, in accordance with embodiments of the present invention.

Under some operating conditions, the incoming flow 710 entering the inlet 715 of the bleed-in reservoir 705 may enter the bleed-in reservoir 705 with air trapped in liquid, a natural result of permeation, turbulence, assembly, etc. Thus, the incoming flow 710 may consist of a mixture of fluids with differing densities, such as a heavier liquid coolant and a lighter gas, such as air. In such cases, the flow through the bleed-in reservoir 705 is typically slower than the flow of coolant through other regions of the cooling loop. Within regions of slower flow, which may include the entire interior volume of the reservoir 705, natural buoyancy effects promote gravitational separation of the incoming flow 710 of fluids. In particular, the lower density fluid (e.g., air) tends to form bubbles 720 that rise toward the headspace region 725 of the bleed-in reservoir 705. The higher density fluid (e.g., liquid coolant) remains predominantly in the lower portion 727 of the bleed-in reservoir 705. As a result, the fluid mixture closer to the headspace region 725 of the bleed-in reservoir 705 typically contains a higher concentration of the lower-density fluid (e.g., air) than the fluid mixture closer to the lower portion 727 of the internal chamber of the bleed-in reservoir 705.

To take advantage of this stratification of the fluid mix in the bleed-in reservoir 705, one or more outlets 730 may be strategically positioned along a wall 735 of the bleed-in reservoir 705 at a predetermined vertical height below the water line 737 in order to permit the outlet 730 to discharge a fluid mix 740 having a chosen ratio of heavier to lighter components, depending on the desired operating conditions or fluid management strategy.

In addition to strategic outlet placement, the position of the inlet may be selected to influence internal flow dynamics. Specifically, the vertical height of the inlet 715 along the reservoir wall 717 can be used to control turbulence within the bleed-in reservoir 705, which may further promote the desired level of gas-liquid separation. For example, in the embodiment illustrated in FIG. 7, the inlet 715 is positioned along the wall 717 of the bleed-in reservoir 705 at a vertical location above the water line 737 (i.e., the liquid coolant-to-gas interface). This relatively higher inlet position may result in the incoming mix of fluid 710 falling into a pool of fluid in the bottom portion 727 of the bleed-in reservoir 705, which may generate greater turbulence at and below the water line 737 leading to increased bubbling 720 below the water line 737 and promote more rapid separation of entrained gases from the liquid coolant.

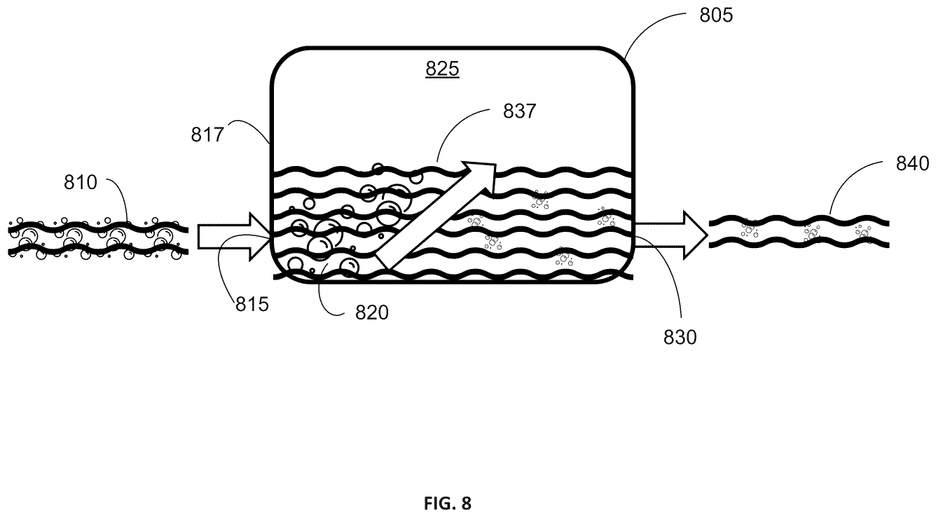

By contrast, FIG. 8 illustrates an alternative embodiment of a bleed-in reservoir 805, in which the inlet 815 is positioned at a lower vertical height along the wall 817, such that the inflow aerated liquid coolant 810 enters the bleed-in reservoir 805 below the water line 837. This arrangement introduces the inflow 810 more gently, with reduced disturbance at the water line 837, leading to less bubbling 820 and establishing a quieter, more stable separation environment.

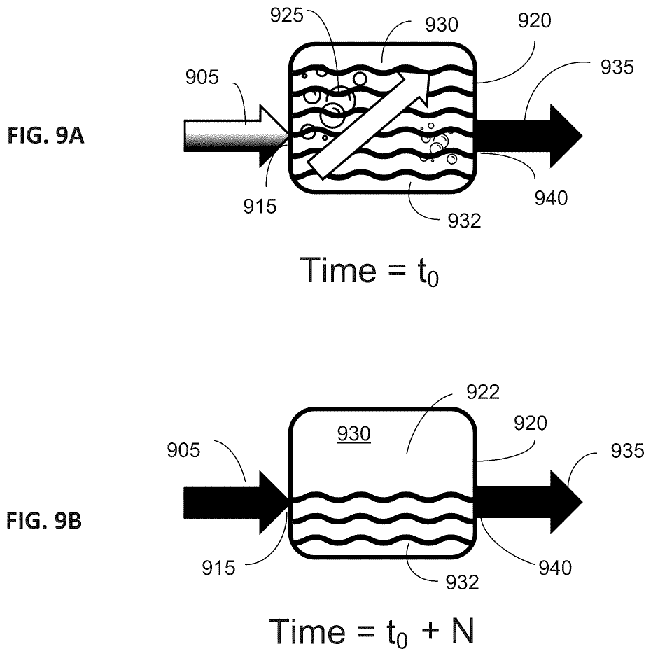

FIGS. 9A and 9B illustrate that separation of air and liquid components within a bleed-in reservoir may require time to reach a steady-state or equilibrium. In particular, FIG. 9A depicts the state of the bleed-in reservoir 920 at an initial time (t₀) when an aerated coolant fluid 905 begins to flow into the bleed-in reservoir 920 through inlet 915.

Gravitational separation occurs when the less dense air component of the aerated coolant fluid 905 begins to disengage from the coolant in the form of bubbles 925, which rise toward the upper region 930 of the reservoir due to buoyancy effects. Because the parallel branch containing the bleed-in reservoir 920 is constructed with smaller-diameter conduits and connectors (not shown in FIGS. 9A and 9B) compared to those in the main cooling loop (not shown in FIGS. 9A and 9B), the flow rate into the bleed-in reservoir 920 is relatively slow compared to the flow rate experienced inside the main cooling loop. This slow flow rate increases the amount of time that the aerated coolant fluid 905 stays inside the bleed-in reservoir 920 before exiting through the outlet 940, providing more time and opportunity for gravitational separation to occur. Meanwhile, the denser liquid coolant of the aerated coolant fluid 905 stays closer to the bottom region 932 of the bleed-in reservoir 920 and will proceed on a more or less direct course to the outlet 940, where it will flow out of the bleed-in reservoir 920.

As a result of this separation process, the coolant fluid 935 discharged from the outlet 940 contains a reduced concentration of entrained gas compared to the incoming aerated fluid 905. Over repeated cycles, the portion of aerated coolant diverted into the parallel branch and through the bleed-in reservoir 920 is progressively de-aerated, allowing the system to gradually approach an equilibrium state in which most of the entrained gas is removed from the main coolant loop and is now concentrated in the headspace region 930 of the bleed-in reservoir 920.

In systems initially filled with aerated coolant, only a fraction of the total fluid volume passes through the bleed-in reservoir 920 during each circulation cycle, due to the flow-limiting geometry of the parallel branch. Consequently, because air and liquid components remain mixed in the main loop, it will take multiple circulation cycles for the entire fluid volume of the system to be processed through the reservoir and de-aerated.

FIG. 9B shows the state of the bleed-in reservoir 920 at a later time t=t₀+N, where N may represent seconds, minutes, hours, or even days later than time t₀, depending on the size and operating parameters of the cooling system. Over time, if the outlet 940 is appropriately positioned to discharge the lower-aeration coolant, the gas content becomes increasingly concentrated in the headspace region 930 of the bleed-in reservoir 920. This process enables progressive gas separation from the circulating fluid, improving the thermal and hydraulic stability of the overall system.

In accordance with certain embodiments of the present invention, the bleed-in reservoir may have one or more flow-diverting structures (not shown in FIGS. 9A and 9B) positioned on inside the internal chamber 922 of the bleed-in reservoir 930. The flow diverter is suitably engineered to disrupt the direct flow of the coolant fluid between the inlet 915 and the outlet 940 of the bleed-in reservoir 905, thereby increasing the residence time of the coolant fluid, promoting turbulence, and enhancing gas-liquid separation. The flow-diverter may also optimize the amount of time the aerated fluid passing through the inlet 915 spends near the water line inside the bleed-in reservoir to ensure a maximum opportunity is provided for the lower-density fluid (air) to separate from the higher-density fluid (liquid coolant) and accumulate in the gas layer within the bleed-in reservoir.

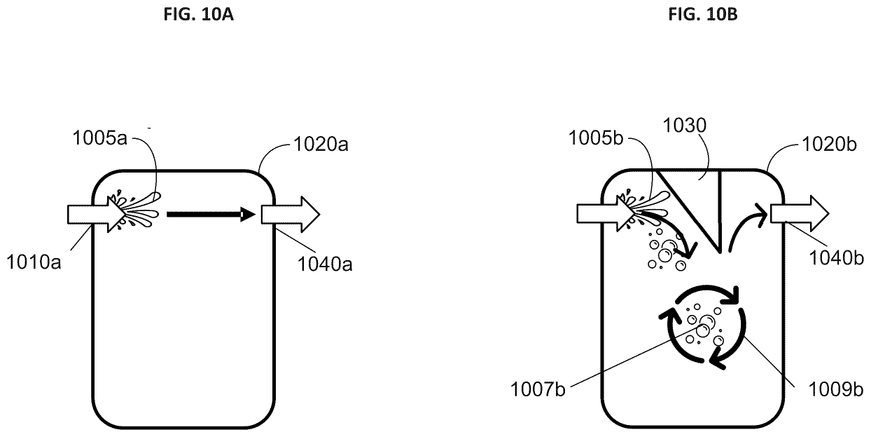

FIGS. 10A and 10B illustrate how a flow-diverting structure located within a bleed-in reservoir can be used to increase the residence time and increase the turbulence of coolant fluid within the bleed-in reservoir, thereby promoting more effective gas-liquid separation.

FIG. 10A presents a top-down schematic view of a bleed-in reservoir 1020a without a flow diverter. As shown, aerated coolant fluid 1005a enters the reservoir through an inlet 1010a. Due to the momentum of the incoming aerated coolant fluid 1005a, a significant portion of the coolant may travel directly from the inlet 1010a to the outlet 1040a located on the opposite wall. This direct flow path may allow the aerated coolant fluid 1005a to exit the bleed-in reservoir 1020a before sufficient gas separation has occurred, thereby reducing the effectiveness of the bleed-in reservoir 1020a in removing entrained air.

In contrast, FIG. 10B shows a schematic top-down view of an alternative embodiment, in which a bleed-in reservoir 1020b includes a flow diverter 1030 mounted to an interior wall of the bleed-in reservoir 1020b. The flow diverter 1030 is positioned directly in the path of the incoming aerated coolant fluid 1005b and is configured to redirect the flow away from the outlet 1040b. By disrupting the direct flow path, the flow diverter 1030 increases the distance that the aerated coolant fluid 1005b must travel and introduces additional turbulence 1007b and circulation 1009b within the bleed-in reservoir 1020b, all of which takes more time. This prolonged residence time inside the bleed-in reservoir 1020b allows more of the entrained air to separate and rise to the liquid coolant-to-air interface before the coolant fluid exits through the outlet 1040b, thereby improving the bleed-in reservoir's 1020b overall gas separation efficiency.

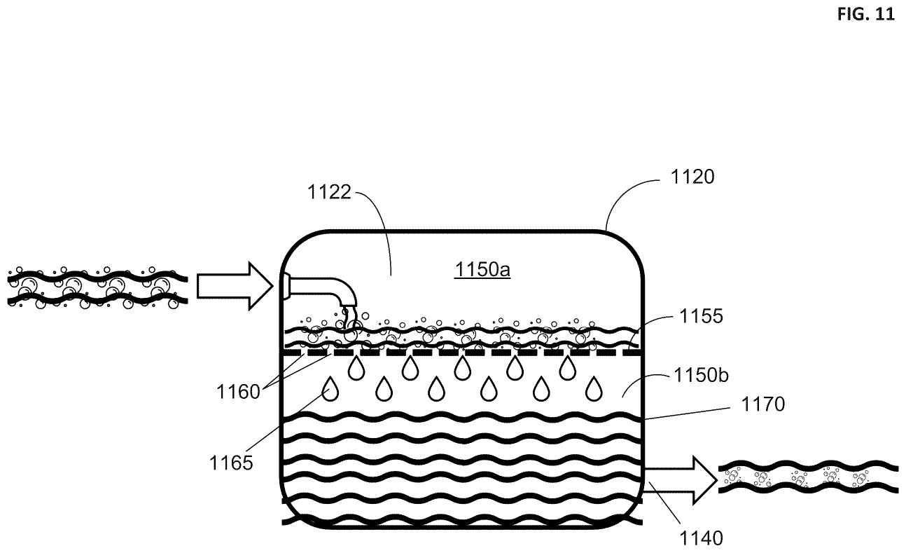

FIG. 11 presents a schematic side view of a bleed-in reservoir 1120 constructed in accordance with another embodiment of the present invention. In this implementation, a perforated horizontal plate 1155 divides the internal chamber 1122 of the bleed-in reservoir 1120 into an upper chamber 1150a and a lower chamber 1150b. The plate 1155 includes multiple small openings 1160 configured to allow liquid coolant to slowly drip 1165 from the upper chamber 1150a into the lower chamber 1150b. This slow transfer of fluid through plate 1155 reduces flow velocity and increases residence time, thereby facilitating the separation of entrained gas from the liquid coolant. As the liquid passes through the small openings 1160, buoyant air bubbles naturally rise and accumulate in the upper chamber 1150a, while degassed liquid accumulates in the lower chamber 1150b.

In some embodiments, the upper chamber 1150a may also include a domed ceiling (not shown in FIG. 11) designed to accommodate and collect rising gas bubbles. Additionally, internal baffle structures may be incorporated above or below the perforated plate 1155 to guide fluid flow, reduce turbulence, or prevent short-circuiting between the inlet and outlet. Notably, the outlet 1140 is suitably positioned below the water line 1170 such that, by the time liquid reaches the outlet 1140, a substantial amount of the entrained gas (air) has been separated from the liquid and accumulated in the headspace of the internal chamber 1122.

This multi-chamber design, combined with gravity-assisted drip separation, passive flow control, selective outlet positioning and optional gas collection features, enhances the bleed-in reservoir's 1120 ability to remove gaseous content from the coolant stream—thus improving overall cooling system performance and operational longevity.

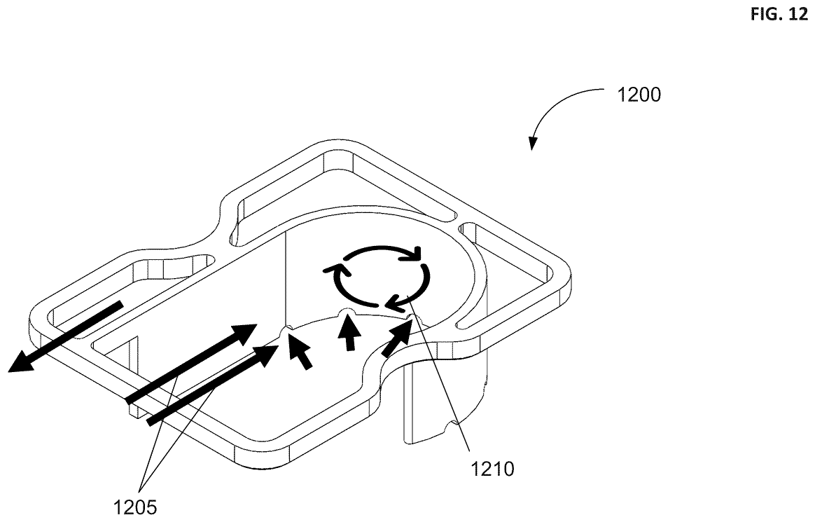

The residence time, turbulence characteristics, flow patterns, and gas separation efficiency within the bleed-in reservoir may be enhanced through the inclusion of variously configured internal inserts. These inserts are designed to increase the opportunity for entrained gas in the incoming coolant flow to disengage, rise, and accumulate within the headspace at the top of the bleed-in reservoir. FIGS. 12-15, which illustrate some examples of such inserts, will now be described immediately below.

FIG. 12 illustrates, by way of example, a rotation-inducing flow-diverting insert 1200. This insert is configured to impart a rotational motion to the incoming coolant fluid 1205 within the bleed-in reservoir. The resulting swirling flow pattern 1210 increases the effective path length and residence time for a given unit volume of coolant, thereby improving opportunities for bubble disengagement and separation.

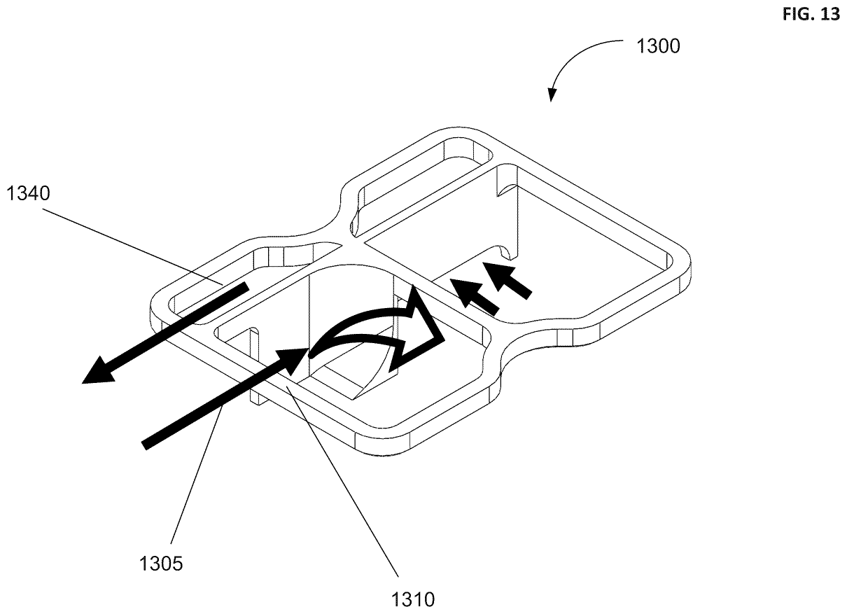

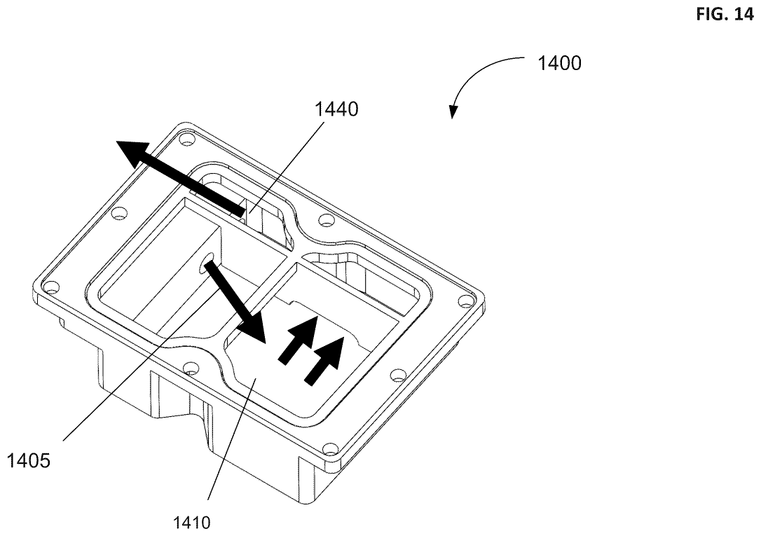

FIG. 13 depicts a redirection-type flow-diverting insert 1300, which is positioned to deflect the incoming coolant flow 1305 away from the outlet 1340. By disrupting liquid coolant that could otherwise follow a direct flow path from the inlet 1310 to the outlet 1340. This insert 1300 extends the residence time inside the internal chamber and reduces the risk of prematurely discharging aerated coolant fluid from the bleed-in reservoir 1300.

FIG. 14 shows a blocking flow-diverting insert 1400, which obstructs the incoming coolant flow 1405 except for the liquid coolant flow along the floor 1410 of the internal chamber of the bleed-in reservoir. This configuration prevents surface-level aeration from passing directly through the insert 1400, and isolates the gas-liquid interface in order to minimize gas carryover to the outlet 1440.

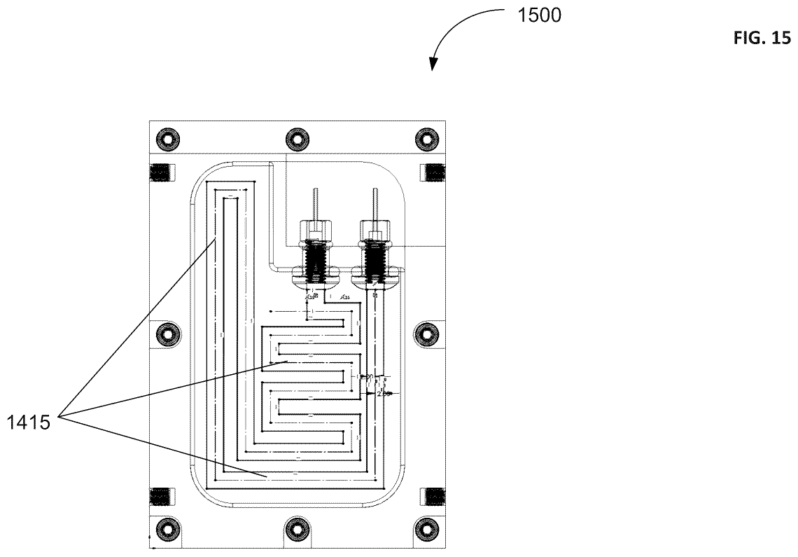

FIG. 15 presents a labyrinth-style flow-diverting insert 1500, designed to force the incoming coolant fluid to travel along a circuitous path 1415 within the reservoir. This insert design maximizes residence time near the surface of the liquid coolant in the internal chamber, allowing entrained gas bubbles to rise and accumulate in the headspace, enhancing degassing performance.

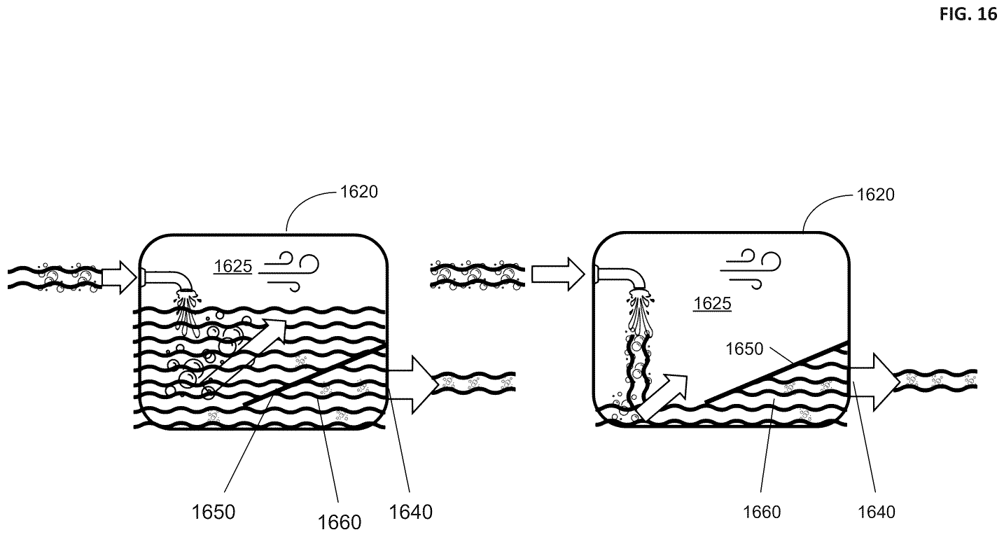

FIG. 16 shows a schematic diagram illustrating an embodiment in which a baffle 1650 is integrated into the internal chamber 1625 of the bleed-in reservoir 1620. The baffle 1650 is configured to define a baffled cavity 1660 located below the baffle 1650 and adjacent to the outlet 1640 of the bleed-in reservoir 1620. The arrangement of the baffle 1650 and the baffled cavity 1660 adjacent to the outlet 1640 improves the usable volume of the cooling system by reducing the submergence requirement of the outlet 1640, thereby helping to delay the onset of gas entrainment during discharge. It does so by lowering the effective outlet height and slowing the velocity of flow entering the baffled cavity 1660. The baffled cavity 1660 remains full, even when the amount of liquid coolant inside the internal chamber 1625 of the bleed-in reservoir is relatively low, due to a vacuum condition arising in the internal chamber 1625. This design effectively increases the usable fluid volume within the bleed-in reservoir 1620 before an operationally significant amount of entrained air reaches the outlet 1640.

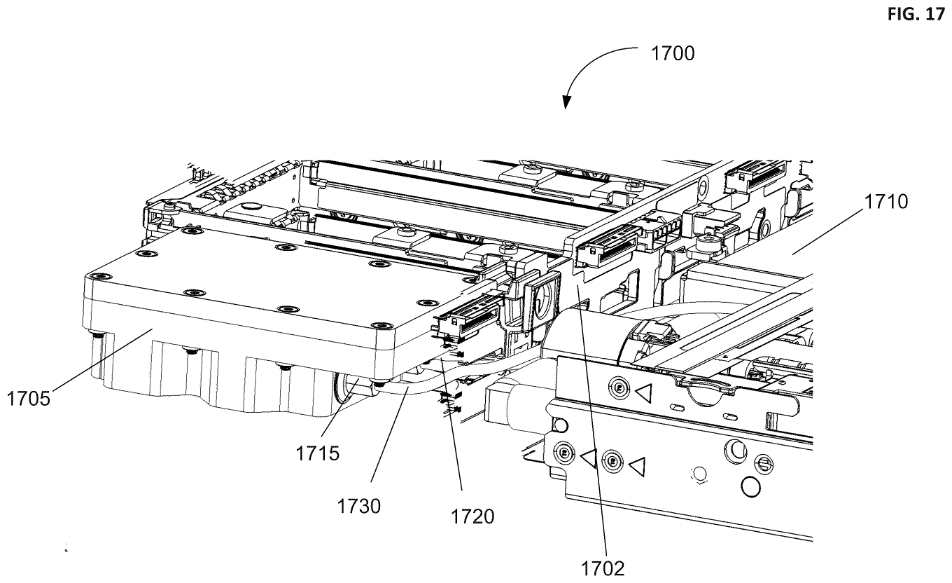

FIG. 17 demonstrates the implementation of a bleed-in reservoir 1705 disposed within a server enclosure 1700 (shown in partial view). As shown in FIG. 17, the bleed-in reservoir 1705 is connected in parallel with a dual-pass radiator 1710, with both the inlet connection 1715 and the outlet connection 1720 connected to the same side of the dual-pass radiator 1710. Beneficially, the use of small-diameter tubing 1730 in the parallel branch of the cooling system allows the bleed-in reservoir 1705 to be located in a region of the server enclosure 1700 typically reserved for hard drives. In the embodiment shown in FIG. 17, for example, the small-diameter tubing 1730 may be routed through existing small openings in the server's backplane 1702. These small openings in the backplane 1702 of the server 1700 are ordinarily used for connections between hard drives and the motherboard.

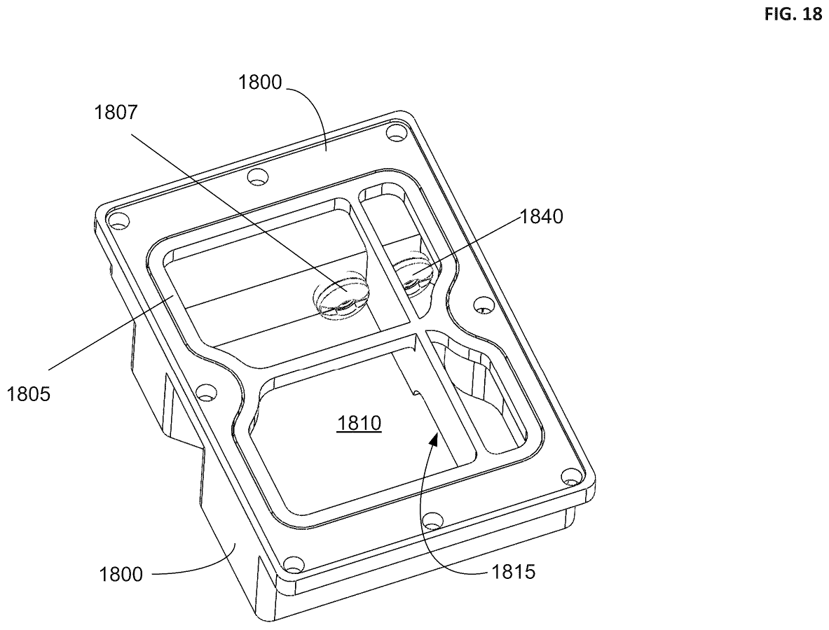

FIG. 18 depicts a bleed-in reservoir 1800 equipped with baffled flow-diverter insert 1805 that manages internal flow to facilitate gas separation. The walls of the insert 1805 define within the bleed-in reservoir 1800 a high-residence-time chamber 1810 that is disposed between the inlet 1807 and an outlet flow passage 1815 that leads to the outlet 1840. The high-residence time chamber 1810 is hydraulically isolated from the outlet flow passage 1815. In particular, the relatively low position of the outlet flow passage 1815 ensures that liquid coolant is drawn from the very bottom of the bleed-in reservoir, maximizing the usable fluid volume before gas entrainment occurs near the outlet 1840 and ensuring that separated gas remains confined to the headspace.

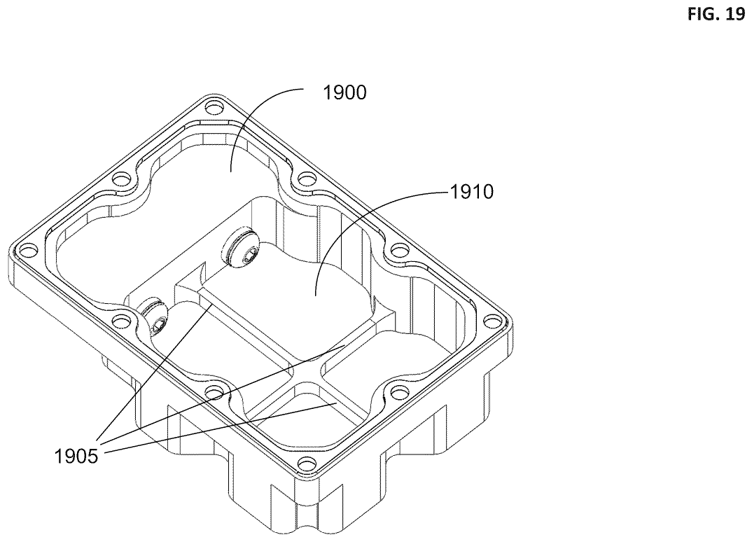

FIG. 19 shows a bleed-in reservoir 1900 with flow-diverters 1905 integrated into the floor 1910 of the bleed-in reservoir 1900. In addition to providing a flow-diverting function, these flow-diverters 1905, which may comprise baffles, for example, also serve a second function; namely providing structural stiffening for the bleed-in reservoir 1900. The flow-diverters also enhance the exposure of incoming coolant fluid to the liquid coolant/air interface, increasing bubble separation and reducing the void fraction of coolant exiting the reservoir and returning to the main AIO loop.

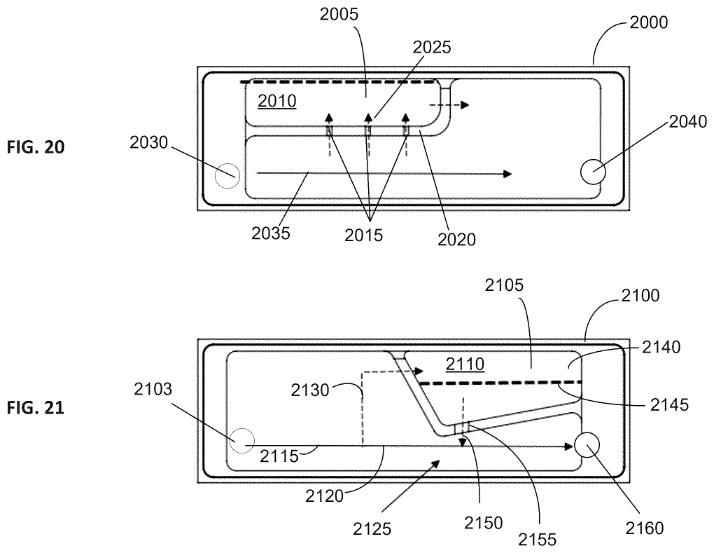

FIG. 20 illustrates an embodiment in which the bleed-in reservoir 2005 is integrated into an endcap 2000 of a radiator (not shown). A reservoir volume 2010 is defined within the endcap 2000, and one or more flow passages 2015 are formed along a wall 2020 of the endcap 2000 to allow a fraction of the aerated liquid coolant 2025 entering the endcap 2000 via the inlet 2030 to be diverted upward into the reservoir volume 2010, while the main coolant flow 2035 continues uninterrupted through the lower portion of the endcap 2000 and exits through the outlet 2040. This design allows the integrated bleed-in reservoir 2005 to intercept only a small, low-velocity portion of the aerated liquid coolant flow-sufficient to allow gravitational gas separation—without significantly disturbing the overall hydraulic performance of the radiator.

In another embodiment shown in FIG. 21, the integrated bleed-in reservoir 2105 comprises a specially contoured reservoir cavity 2110 formed in the endcap 2100 of a radiator (not shown). The aerated liquid coolant 2115 entering the endcap 2100 via inlet 2103 is divided into two streams: a primary stream 2120 that flows along the lower portion of the channel 2125 and a secondary stream 2130 that is diverted upward into the reservoir cavity 2110. Within the integrated bleed-in reservoir 2105, buoyancy forces drive the separation of air from the liquid coolant, allowing an air blanket 2140 to form above the coolant level 2145. The de-aerated coolant 2150 then exits the reservoir cavity 2110 through a downward-sloping outlet channel 2155 that returns it to the main flow channel 2125, where it then flows out of the endcap 2105 via outlet 2160. This internal routing effectively places the secondary stream 2130 flowing through the integrated bleed-in reservoir 2105 in a flow-parallel configuration with the primary coolant stream 2120 flowing through main flow channel 2125, achieving gas separation benefits without the need for external fluid junction fittings, tubing or connectors.

The above-described preferred embodiments are intended to illustrate the principles of the invention, but not to limit its scope. Various other embodiments, modifications and equivalents to these preferred embodiments may occur to those skilled in the art upon reading the present disclosure or practicing the claimed invention. Such variations, modifications and equivalents are intended to come within the scope of the invention and the appended claims.

What is claimed is:

1. A liquid cooling system for a heat-generating electronic device, comprising:
a main cooling loop comprising a pump, a radiator, a cooling module configured to be put in thermal communication with the heat-generating electronic device, and a set of primary fluid conduits that fluidly connect the pump, the radiator and the cooling module in series to define a closed-loop flow path for circulating a liquid coolant at a first flow rate;
a parallel branch comprising a set of secondary fluid conduits connected in series to a bleed-in reservoir, the bleed-in reservoir having an internal chamber comprising an inlet for admitting liquid coolant into the internal chamber, an outlet for discharging liquid coolant from the internal chamber and headspace for holding a volume of compressible gas;
two fluid junction fittings connecting the set of secondary fluid conduits of the parallel branch to the main cooling loop so that the parallel branch is connected in parallel with a section of the main cooling loop and a portion of the liquid coolant circulating in the main cooling loop is redirected to flow through the parallel branch and the bleed-in reservoir before returning to the main cooling loop;
wherein
(i) the set of secondary fluid conduits in the parallel branch are constructed to have a smaller diameter than the primary fluid conduits in the main cooling loop to ensure a reduced flow rate for the portion of the liquid coolant flowing through the parallel branch compared to the first flow rate for the liquid coolant circulating through the main cooling loop, and
(ii) the internal chamber of the bleed-in reservoir is configured to promote a separation of gas from the portion of the liquid coolant flowing therethrough and to confine the separated gas in the headspace.

2. The liquid cooling system of claim 1, wherein the section of the main cooling loop in parallel with the bleed-in reservoir includes the pump and does not include the radiator or the cooling module.

3. The liquid cooling system of claim 1, wherein the section of the main cooling loop in parallel with the bleed-in reservoir includes the radiator and does not include the pump or the cooling module.

4. The liquid cooling system of claim 1, wherein the section of the main cooling loop in parallel with the parallel branch includes the cooling module and does not include the pump or the radiator.

5. The liquid cooling system of claim 1, wherein the section of the main cooling loop in parallel with the bleed-in reservoir includes the primary fluid conduits and does not include the pump, the radiator or the cooling module.

6. The liquid cooling system of claim 1, wherein the section of the main cooling loop in parallel with the bleed-in reservoir includes both the pump and the radiator.

7. The liquid cooling system of claim 1, wherein the section of the main cooling loop in parallel with the bleed-in reservoir includes both the pump and the cooling module.

8. The liquid cooling system of claim 1, wherein the section of the main cooling loop in parallel with the bleed-in reservoir includes both the radiator and the cooling module.

9. The liquid cooling system of claim 1, further comprising a flow-modifying feature within the internal chamber of the bleed-in reservoir, the flow-modifying feature configured to increase residence time of the liquid coolant inside the internal chamber.

10. The liquid cooling system of claim 9, wherein the flow-modifying feature comprises a flow-diverter configured to disrupt quiescent flow of the liquid coolant inside the internal chamber.

11. The liquid cooling system of claim 9, wherein the flow-modifying feature comprises a flow-diverter, positioned between the inlet and the outlet, the flow-diverter configured to redirect the portion of liquid coolant passing into the internal chamber via the inlet so that the portion of liquid coolant cannot flow directly to the outlet:

12. The liquid cooling system of claim 1, further comprising a perforated plate dividing the internal chamber of the bleed-in reservoir into an upper chamber and a lower chamber, the perforated plate having multiple openings configured to allow liquid coolant to drip from the upper chamber into the lower chamber to promote the gas separation and to increase residence time of the portion of liquid coolant inside the internal chamber.

13. The liquid cooling system of claim 1, further comprising:
a baffle located inside the internal chamber of the bleed-in reservoir, the baffle arranged to define a baffled cavity located between the baffle and the outlet;
wherein the baffle is positioned to reduce the flow rate of liquid coolant flowing into the baffled cavity and lower a minimum effective height for the outlet by establishing or increasing a vacuum condition inside the internal chamber.

14. The liquid cooling system of claim 1, further comprising a rotation-inducing flow-diverting insert positioned inside the internal chamber of the bleed-in reservoir configured to impart a rotational swirling motion to the liquid coolant passing into the internal chamber of the bleed-in reservoir via the inlet.

15. The liquid cooling system of claim 1, further comprising a redirection-type insert positioned inside the internal chamber of the bleed-in reservoir configured to deflect the liquid coolant away from the outlet.

16. The liquid cooling system of claim 1, further comprising a blocking flow-diverting insert positioned inside the internal chamber of the bleed-in reservoir configured to obstruct a part of the liquid coolant flowing into the internal chamber of the bleed-in reservoir without obstructing liquid coolant flowing along a bottom region of the internal chamber.

17. The liquid cooling system of claim 1, further comprising a labyrinth-styled insert positioned inside the internal chamber of the bleed-in reservoir, labyrinth-style insert having a labyrinthian flow path to increase residence time of the liquid coolant inside the internal chamber of the bleed-in reservoir.

18. The liquid cooling system of claim 1, wherein the separation of gas from the portion of liquid coolant flowing through the internal chamber of the bleed-in reservoir creates a liquid coolant-to-gas interface inside the internal chamber; and
the inlet of the bleed-in reservoir is vertically positioned along a wall of the internal chamber at a height that is above the liquid coolant-to-gas interface.

19. The liquid cooling system of claim 1, wherein
the separation of gas from the portion of liquid coolant flowing through the internal chamber of the bleed-in reservoir creates a liquid coolant-to-gas interface inside the internal chamber; and
the inlet of the bleed-in reservoir is vertically positioned along a wall of the internal chamber at a height that is below the liquid coolant-to-gas interface.

20. The liquid cooling system of claim 1, wherein multiple bleed-in reservoirs are connected in series along the parallel branch.

21. The liquid cooling system of claim 1, wherein the one of the two fluid junction fittings connects the parallel branch directly to a quiescent zone within the main cooling loop.

22. The liquid cooling system of claim 21, wherein the quiescent zone comprises a plenum region of the radiator.

23. The liquid cooling system of claim 21, wherein the quiescent zone comprises a plenum region of the cooling module.

24. The liquid cooling system of claim 21, wherein the quiescent zone comprises a low-velocity chamber in the cooling module.

25. A method of operating a liquid cooling system for a heat-generating electronic device, comprising the steps of:
circulating a liquid coolant through a main cooling loop at a first flow rate, the main cooling loop comprising a pressure source, a radiator and a cooling module in thermal communication with the heat-generating electronic device, and;
diverting a portion of the liquid coolant to flow out of the main cooling loop and through a bleed-in reservoir that is connected in parallel to a section of the main cooling loop, the bleed-in reservoir comprising an internal chamber having an inlet for receiving the portion of liquid coolant, and outlet for discharging the portion of liquid coolant, and headspace for capturing a volume of compressible gas;
maintaining a second flow rate through the bleed-in reservoir that is lower than the first flow rate;
permitting gas in the portion of liquid coolant flowing through the bleed-in reservoir to be separated from the liquid coolant and confined in the headspace of the internal chamber; and
preventing the gas confined in the headspace of the internal chamber from reentering the main cooling loop.

26. The method of claim 25, further comprising redirecting incoming coolant inside the bleed-in reservoir using a flow diverter to increase residence time and turbulence.

27. The method of claim 25, further comprising passing the portion of liquid coolant through a perforated plate positioned in the internal chamber to enhance gas separation in the internal chamber.

28. The method of claim 25, further comprising positioning the outlet of the internal chamber below a liquid coolant-to-air interface inside the internal chamber so that any liquid coolant discharged from the internal chamber by the outlet will be drawn from a lower region of the internal chamber.

29. The method of claim 25, further comprising positioning a baffle inside the internal chamber to establish or enhance a vacuum condition inside the internal chamber, and thereby reduce a minimum effective height of an outlet in the internal chamber to increase usable coolant volume in the internal chamber of the bleed-in reservoir.

30. The method of claim 25, further comprising positioning the inlet of the internal chamber at a vertical height that lies above a liquid coolant-to-air interface in the internal chamber to increase turbulence inside the internal chamber.

31. The method of claim 25, further comprising positioning the inlet of the internal chamber at a vertical height that lies below a liquid coolant-to-air interface in the internal chamber to decrease turbulence inside the internal chamber.

32. The method of claim 25, further comprising connecting multiple bleed-in reservoirs in series to increase gas separation capacity.

33. The method of claim 25, further comprising fluidly connecting the inlet of the internal chamber to a quiescent zone within the main cooling loop.

34. The method of claim 33, wherein the quiescent zone comprises a plenum region of the radiator.

35. The method of claim 33, wherein the quiescent zone comprises a plenum region of the cooling module.

36. The method of claim 33, wherein the quiescent zone comprises a low-velocity chamber in the cooling module.

37. A liquid cooling system for an electronic device, comprising:
a main cooling loop configured to circulate liquid coolant through a pump, a radiator, and a cooling module;
an integrated bleed-in reservoir disposed within or attached to one of the components of the main cooling loop, the integrated bleed-in reservoir comprising an internal chamber configured to hold a volume of liquid coolant and a volume of gas;
wherein a portion of the liquid coolant flowing through the main cooling loop passes into the internal chamber of the integrated bleed-in reservoir, while a remainder of the liquid coolant continues through the main cooling loop.

38. The liquid cooling system of claim 37, wherein the integrated bleed-in reservoir is disposed in an endcap or fluid connector attached to a downstream side of the radiator.

39. The liquid cooling system of claim 37, wherein the integrated bleed-in reservoir is disposed within a pump housing, radiator housing, or cooling module housing.

40. The liquid cooling system of claim 37, wherein a wall of the integrated bleed-in reservoir includes a passage configured to divert the portion of the liquid coolant into the internal chamber from a low-pressure region of the main cooling loop.

41. The liquid cooling system of claim 37, wherein the internal chamber is positioned above a primary flow channel of the main cooling loop and is configured to accumulate a gas blanket in an upper portion of the internal chamber.

42. The liquid cooling system of claim 37, wherein the internal chamber includes an outlet passage configured to return de-aerated coolant to the main cooling loop from a region below a liquid coolant-to-gas interface.

43. The liquid cooling system of claim 37, wherein the internal chamber of the integrated bleed-in reservoir includes an internal baffle or flow-diverting feature configured to reduce flow velocity and increase residence time of the liquid coolant inside the internal chamber.

44. The liquid cooling system of claim 38, wherein the endcap is configured for use with a dual-pass radiator.

45. A method of managing gas separation in a liquid cooling system comprising a main cooling loop, the method comprising:
circulating liquid coolant through the main cooling loop, the main cooling loop comprising a pump, a radiator, and a cooling module;
diverting a portion of the circulating liquid coolant into an internal chamber of an integrated bleed-in reservoir disposed within or attached to one of the components of the main cooling loop;
allowing gas to separate from the portion of liquid coolant inside the internal chamber of the integrated bleed-in reservoir; and
returning at least part of the de-aerated liquid coolant from the internal chamber to the main cooling loop.

46. The method of claim 45, wherein the integrated bleed-in reservoir is disposed in an endcap or fluid connector attached to a downstream side of the radiator.

47. The method of claim 45, wherein the integrated bleed-in reservoir is formed within an endcap of a dual-pass radiator.

48. The method of claim 45, wherein the step of diverting comprises directing the portion of the liquid coolant through a passage formed in a wall of the endcap or fluid connector.

49. The method of claim 45, wherein the step of allowing gas to separate comprises accumulating a gas blanket in an upper portion of the internal chamber.

50. The method of claim 45, wherein the step of returning the de-aerated coolant comprises directing the de-aerated coolant downward along a sloped passage into the main flow of the main cooling loop.

51. The method of claim 45, wherein the portion of the liquid coolant is diverted from a low-pressure region of the main cooling loop.

52. The method of claim 45, wherein the portion of the liquid coolant is diverted and returned without the use of external fluid junction fittings.

53. An endcap for a liquid cooling system component, the endcap comprising:
a coolant flow channel configured to receive a flow of liquid coolant through a main cooling loop of the liquid cooling system;
an integrated bleed-in reservoir comprising an internal chamber configured to hold both liquid coolant and gas;
a fluid communication passage configured to divert a portion of the liquid coolant from the coolant flow channel into the internal chamber of the integrated bleed-in reservoir; and
an outlet passage configured to return de-aerated coolant from the internal chamber to the main cooling loop.

54. The endcap of claim 53, wherein the integrated bleed-in reservoir is disposed above the coolant flow channel.

55. The endcap of claim 53, wherein the internal chamber comprises a gas accumulation region located above a coolant level line.

56. The endcap of claim 53, wherein the outlet passage is positioned below the coolant level line in the internal chamber.

57. The endcap of claim 53, further comprising an internal baffle or flow-directing structure configured to reduce flow velocity within the internal chamber.

58. The endcap of claim 53, wherein the endcap is configured to be attached to a dual-pass radiator.

59. The endcap of claim 53, wherein the coolant flow channel and the integrated bleed-in reservoir are formed as a unitary structure.
